(19) United States
(12) Patent Application Publication
(10) Pub. No.: US 2025/0199030 A1
(43) Pub. Date: Jun. 19, 2025

(54) CHIP TESTING DEVICE AND METHOD OF OPERATING THEREOF

(71) Applicant: KINGTIGER TESTING INC., Markham (CA)

(72) Inventors: Aihua Wang, Shenzhen (CN); Bosco Lai, Hong Kong (CN)

(21) Appl. No.: 18/846,598

(22) PCT Filed: Mar. 15, 2022
(86) PCT No.: PCT/CA2022/050379

§ 371 Date: Sep. 12, 2024

(51) Int. Cl. G01R 1/04; G01R 31/28

(52) U.S. Cl. CPC G01R 1/0466; G01R 31/2886

(57) ABSTRACT

A chip testing device and a method of operating thereof is provided herein. According to at least one embodiment, the chip testing device comprises: a test board having at least one mounting surface; at least one chip socket located on one of the at least one mounting surface, wherein each of the at least one chip socket comprises: a positioning fixture mounted to the at least one mounting surface, the positioning fixture defining a mounting area for mounting a chip; a sliding cover that is slidably moveable between an open position and a closed position, wherein, in the open position, the mounting area is at least partially exposed to allow for mounting of the chip, and in the closed position, the cover overlays at least a portion of the chip and the positioning fixture.

### FIELD

Various embodiments are described herein that generally relate to electronic devices, and in particular, to a chip testing device and method of operating thereof.

### BACKGROUND

The following is not an admission that anything discussed below is part of the prior art or part of the common general knowledge of a person skilled in the art.

Chip testing devices are commonly used for testing integrated circuit chips (i.e., random access memory (RAM) chips) during the design and development phases. A chip testing device typically includes one or more chip sockets, each socket configured to removably receive a single test chip. Once chips are mounted into the device's sockets, the device as a whole may be plugged into a computer motherboard to test the functionality of each chip. Chips determined, via testing, to perform below expectations may be removed from the device, and otherwise reconfigured or dispensed of. In this manner, chip testing devices provide a convenient mechanism for facilitating rapid installation, testing and deinstallation of test chips without requiring these chips to be fully soldered and de-soldered onto a motherboard with each test run.

### SUMMARY OF VARIOUS EMBODIMENTS

The following introduction is provided to introduce the reader to the more detailed discussion to follow. The introduction is not intended to limit or define any claims or as yet unclaimed invention. One or more inventions may reside in any combination or sub-combination of the elements or process steps disclosed in any part of this document including its claims and figures

According to one aspect of the present subject matter, there is disclosed a chip testing device comprising: a test board having at least one mounting surface; at least one chip socket located on one of the at least one mounting surface, wherein each of the at least one chip socket comprises: a positioning fixture mounted to the at least one mounting surface, the positioning fixture defining a mounting area for mounting a chip; a sliding cover that is slidably moveable between an open position and a closed position, wherein, in the open position, the mounting area is at least partially exposed to allow for mounting of the chip, and in the closed position, the cover overlays at least a portion of the chip and the positioning fixture.

In at least some embodiments, the test board comprises a planar printed circuit board (PCB) having two opposed mounting surfaces.

In at least some embodiments, the sliding cover is slidably engaged to the positioning fixture.

In at least some embodiments, one end the sliding cover includes a limiting plate that is adapted to delimit sliding of the sliding cover beyond the closed position.

In at least some embodiments, the sliding cover comprises a clamping member located at an opposite end relative to end of the sliding cover that includes the limiting plate, and wherein the of the positioning fixture comprises a clamping slot that is compatible with the clamping member, and engagement of the clamping member and the clamping slot releasably secures the sliding cover in the closed position.

In at least some embodiments, the positioning fixture comprises a frame structure having a first edge, and a second edge opposite the first edge, wherein, each of the first and second edges extend along a first axis of the test board between a respective first end and a respective opposed second end, and each of the first and second edges define an area located therebetween that comprises the mounting area.

In at least some embodiments, the sliding cover is adapted to slide between the open position and the closed position along a translation axis that is parallel to the first axis.

In at least some embodiments, the sliding cover is adapted to slide from the open position to the closed position by sliding from the respective first end, of each of the first and second edges, towards the respective second end.

In at least some embodiments, at least a portion of at least one of the first and second edges comprises a protruding convex strip, and the sliding cover comprises at least one flanged member that is adapted to mate in a sliding engagement with the protruding convex strip.

In at least some embodiments, the positioning fixture further comprises a third edge and an opposed fourth edge, wherein each of the third and fourth edges extend between the first and second edges, and wherein each of the third and fourth edges extend along a second axis that is transverse to the first axis.

In at least some embodiments, the chip test device further comprises a rotatable flipping member that rotates between an unrotated position and a rotated position, wherein in the unrotated position, the rotatable member extends away from the at least one mounting surface to at least partially expose the mounting area, and in the rotated position, the rotatable member is rotated toward the at least one mounting surface to at least partially cover the mounting area.

In at least some embodiments, the rotatable member is rotatably mounted to the third edge of the positioning fixture.

In at least some embodiments, at least a portion of the third edge of the positioning fixture defines a rotatable hinge structure for rotatably mounting the rotatable member.

In at least some embodiments, the chip test device further comprises a biasing member to bias the rotating member in the unrotated position.

In at least some embodiments, the biasing member comprises a biasing spring.

In at least some embodiments, the sliding cover is adapted to move the rotatable member from the unrotated position to the rotated position when the sliding cover is translated from the open position to the closed position.

In at least some embodiments, when the sliding cover is in the closed position, the rotatable member is located between the sliding cover and the mounting area.

In at least some embodiments, one or more electrical contact pads are located in the mounting area, the one or more electrical contact pads being configured to electrical connect to electrical pins located on the chip mounted in the mounting area.

In at least some embodiments, the test board further comprises an insertion portion for electrically and mechanically coupling the device with a motherboard and the insertion portion comprises one or more electrical pins that are electrically connected to the one or more electrical contact pads.

In at least some embodiments, the insertion portion extends along an edge of the board.

In at least some embodiments, the at least one mounting surface comprises a plurality of chip sockets.

In at least some embodiments, the plurality of chip sockets are serially arranged along a longitudinal axis of the mounting surface.

In at least some embodiments, the at least one mounting surface comprises a first surface and an opposed second surface, and the plurality of chip sockets are located on each of the first and second surfaces.

In at least some embodiments, the positioning fixture includes one or more mounting holes, and the positioning fixture is mounted to the at least one surface of the test board using one or more fasteners that releasably engage the mounting holes.

According to another aspect of the present subject matter, there is disclosed a chip testing device comprising: a test board having at least one mounting surface; at least one chip socket located on one of the at least one mounting surface, wherein each of the at least one chip socket comprises: a positioning fixture mounted to the at least one mounting surface, the positioning fixture defining a mounting area for mounting a chip; a sliding cover that is slidably moveable between an open position and a closed position, and a rotatable flipping member that rotates between an unrotated position and a rotated position, wherein, in the open position of the sliding cover, the mounting area is at least partially exposed to allow for mounting of the chip, and in the closed position of the sliding cover, the cover overlays at least a portion of the chip and the positioning fixture, and in the unrotated position of the rotatable member, the rotatable member extends away from the at least one mounting surface to at least partially expose the mounting area, and in the rotated position of the rotatable member, the rotatable member is rotated toward the at least one mounting surface to at least partially cover the mounting area.

In at least some embodiments, the rotatable member is rotatably mounted to an edge of the positioning fixture.

In at least some embodiments, at least a portion of the edge of the positioning fixture defines a rotatable hinge structure for rotatably mounting the rotatable member.

In at least some embodiments, the chip test device further comprises a biasing member to bias the rotating member in the unrotated position.

In at least some embodiments, the biasing member comprises a biasing spring.

In at least some embodiments, the sliding cover is adapted to move the rotatable member from the unrotated position to the rotated position when the sliding cover is translated from the open position to the closed position.

In at least some embodiments, when the sliding cover is in the closed position, the rotatable member is located between the sliding cover and the mounting area.

According to another aspect of the present subject matter, there is disclosed a method of operating a chip testing device, the method comprising: positioning a sliding cover in an open position; inserting a chip in a mounting area, the mounting area being defined by a positioning fixture mounted to a surface of a test board of the chip testing device, the sliding cover being movably coupled to the positioning fixture; and translating the sliding cover from the open position to the closed position.

In at least some embodiments, during the translating, the method further comprises: rotating a flipping member from an unrotated position to a rotated position, wherein in the closed position, the flipping member is located between the sliding cover and the chip.

Other features and advantages of the present application will become apparent from the following detailed description taken together with the accompanying drawings. It should be understood, however, that the detailed description of the specific examples, while indicating preferred embodiments of the application, are given by way of illustration only, since various changes and modifications within the spirit and scope of the application will become apparent to those skilled in the art from this detailed description.

### BRIEF DESCRIPTION OF THE DRAWINGS

For a better understanding of the various embodiments described herein, and to show more clearly how these various embodiments may be carried into effect, reference will be made, by way of example, to the accompanying drawings which show at least one example embodiments, and which are now described. The drawings are not intended to limit the scope of the teachings described herein.

FIG. 1 is a schematic illustration of an example motherboard with one or more chip testing devices.

FIG. 2A illustrates a perspective view of an example conventional chip testing device, wherein the chip testing device is in an open position.

FIG. 2B illustrates a perspective view of the chip testing device of FIG. 2A in a closed position.

FIG. 3 illustrates a side perspective view of an example embodiment of a chip testing device in accordance with the teachings herein.

FIG. 4 illustrates a side elevation view of the chip testing device of FIG. 3 in accordance with the teachings herein.

FIG. 5 illustrates an enlarged side elevation view of a portion of the chip testing of FIG. 3.

FIG. 6 illustrates a bottom plan view of the chip testing device of FIG. 3.

FIG. 7 illustrates an enlarged bottom plan view of a portion of the chip testing device of FIG. 3.

FIG. 8A illustrates a perspective view of a chip testing device with one or more sliding covers in an open position and one or more rotating members in the unrotated position.

FIG. 8B illustrates a perspective view of the chip testing device of FIG. 8A with the one or more sliding covers in an open position and at least one rotating member in the rotated position.

FIG. 8C illustrates a perspective view of the chip testing device of FIG. 8A with the one or more sliding covers in a partially closed position.

FIG. 8D illustrates a perspective view of the chip testing device of FIG. 8A with the one or more sliding covers in the closed position.

FIG. 9 illustrates an example embodiment of a process for operating a chip testing device, in accordance with the teachings herein.

Further aspects and features of the example embodiments described herein will appear from the following description taken together with the accompanying drawings.

### DETAILED DESCRIPTION OF THE EMBODIMENTS

Various embodiments in accordance with the teachings herein are described to provide an example of at least one embodiment of the claimed subject matter. No embodiment described herein limits any claimed subject matter. The claimed subject matter is not limited to devices, systems or methods having all of the features of any one of the devices, systems or methods described below or to features common to multiple or all of the devices, systems or methods described herein. It is possible that there may be a device, system or method described herein that is not an embodiment of any claimed subject matter. Any subject matter that is described herein that is not claimed in this document may be the subject matter of another protective instrument, for example, a continuing patent application, and the applicants, inventors or owners do not intend to abandon, disclaim or dedicate to the public any such subject matter by its disclosure in this document.

It will be appreciated that for simplicity and clarity of illustration, where considered appropriate, reference numerals may be repeated among the figures to indicate corresponding or analogous elements or steps. In addition, numerous specific details are set forth in order to provide a thorough understanding of the example embodiments described herein. However, it will be understood by those of ordinary skill in the art that the embodiments described herein may be practiced without these specific details. In other instances, well-known methods, procedures and components have not been described in detail so as not to obscure the embodiments described herein. Also, the description is not to be considered as limiting the scope of the example embodiments described herein.

It should also be noted that the terms “coupled” or “coupling” as used herein can have several different meanings depending in the context in which these terms are used. For example, the terms coupled, or coupling can have a mechanical, fluidic or electrical connotation. For example, as used herein, the terms coupled or coupling can indicate that two elements or devices can be directly connected to one another or connected to one another through one or more intermediate elements or devices via an electrical or magnetic signal, electrical connection, an electrical element or a mechanical element depending on the particular context. Furthermore, coupled electrical elements may send and/or receive data.

Unless the context requires otherwise, throughout the specification and claims which follow, the word “comprise” and variations thereof, such as, “comprises” and “comprising” are to be construed in an open, inclusive sense, that is, as “including, but not limited to”.

It should also be noted that, as used herein, the wording “and/or” is intended to represent an inclusive-or. That is, “X and/or Y” is intended to mean X or Y or both, for example. As a further example, “X, Y, and/or Z” is intended to mean X or Y or Z or any combination thereof.

It should be noted that terms of degree such as “substantially”, “about” and “approximately” as used herein mean a reasonable amount of deviation of the modified term such that the end result is not significantly changed. These terms of degree may also be construed as including a deviation of the modified term, such as by 1%, 2%, 5% or 10%, for example, if this deviation does not negate the meaning of the term it modifies.

Furthermore, the recitation of numerical ranges by endpoints herein includes all numbers and fractions subsumed within that range (e.g., 1 to 5 includes 1, 1.5, 2, 2.75, 3, 3.90, 4, and 5). It is also to be understood that all numbers and fractions thereof are presumed to be modified by the term “about” which means a variation of up to a certain amount of the number to which reference is being made if the end result is not significantly changed, such as 1%, 2%, 5%, or 10%, for example.

Reference throughout this specification to “one embodiment”, “an embodiment”, “at least one embodiment” or “some embodiments” means that one or more particular features, structures, or characteristics may be combined in any suitable manner in one or more embodiments, unless otherwise specified to be not combinable or to be alternative options.

As used in this specification and the appended claims, the singular forms “a,” “an,” and “the” include plural referents unless the content clearly dictates otherwise. It should also be noted that the term “or” is generally employed in its broadest sense, that is, as meaning “and/or” unless the content clearly dictates otherwise.

The headings and Abstract of the Disclosure provided herein are for convenience only and do not interpret the scope or meaning of the embodiments.

Similarly, throughout this specification and the appended claims the term “communicative” as in “communicative pathway,” “communicative coupling,” and in variants such as “communicatively coupled,” is generally used to refer to any engineered arrangement for transferring and/or exchanging information. Exemplary communicative pathways include, but are not limited to, electrically conductive pathways (e.g., electrically conductive wires, electrically conductive traces), magnetic pathways (e.g., magnetic media), optical pathways (e.g., optical fiber), electromagnetically radiative pathways (e.g., radio waves), or any combination thereof. Exemplary communicative couplings include, but are not limited to, electrical couplings, magnetic couplings, optical couplings, radio couplings, or any combination thereof.

Throughout this specification and the appended claims, infinitive verb forms are often used. Examples include, without limitation: “to detect,” “to provide,” “to transmit,” “to communicate,” “to process,” “to route,” and the like. Unless the specific context requires otherwise, such infinitive verb forms are used in an open, inclusive sense, that is as “to, at least, detect,” to, at least, provide,” “to, at least, transmit,” and so on.

The terms “installation”, “connection”, and “connection” as used herein are understood in a broad sense. For example, these terms may refer to a fixed connection, a detachable connection, an integral connection, a mechanical connection, an electrical connection, a direct connection, an indirect connection, i.e., through an intermediate component or medium, and/or an internal communication between two components. For those of ordinary skill in the art, the meaning of the above-mentioned terms can be understood through the context they are used in.

The terms “center”, “vertical”, “horizontal”, “upper”, “lower”, “front”, “rear”, “left”, “right”, and the orientation and/or positional relationship indicated by “vertical”, “horizontal”, “top”, “bottom”, “inner”, “outer” etc. may be based on the orientation or positional relationship as, for example, shown in the drawings, and is only provided for the convenience of explanation and/or description. It will be understood, however, that these terms do not otherwise limit the described embodiments to a specific orientation and/or limit the embodiment to a necessary specification orientation for construction, use and/or operation.

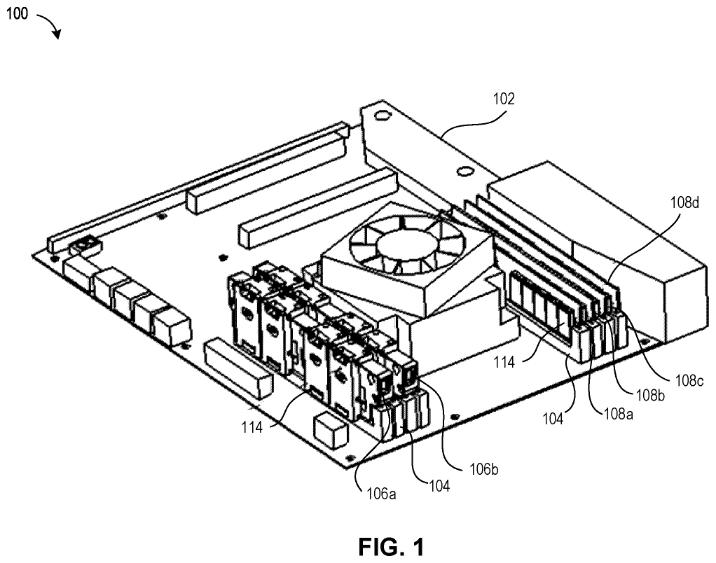

Reference is now made to FIG. 1, which schematically illustrates an example motherboard assembly 100, in accordance with some embodiments.

Motherboard assembly 100 includes a motherboard 102, also referred to herein as a main circuit board, or a main board. Motherboard 102 may comprise a printed circuit board (PCB) having one or more electrical connections for coupling together various mounted electrical components, e.g., a central processing unit (CPU), non-volatile memory cards, fans, etc.

Motherboard 102 may also include one or more electrical interfaces 104. Each electrical interface 104 can comprise a slot for receiving a memory board chip. In at least one embodiment, each electrical interface 104 may be adapted to receive a dual in-line memory module (DIMM), also known as random-access memory (RAM) stick, that includes a series of soldered RAM integrated circuit chips, or dynamic RAM (dRAM) integrated circuit chips.

Motherboard assembly 100 also includes a plurality of chip testing devices 106, 108. Each of the chip testing devices 106, 108 may be received in a separate electrical interface 104. As provided in the background, chip testing devices 106, 108 are commonly used for testing and assessing performance of test chips and are often deployed in semi and fully automated production processes. Each chip testing device 106, 108 can include one or more chip sockets 114 to retain one or more test chips (i.e., integrated circuit (IC) chips, RAM chips, etc.). The test chips can be tested by connecting the respective chip testing devices 106, 108 to the motherboard 102.

In the illustrated example, the motherboard assembly 100 is shown as including two types of chip testing devices: (i) chip testing devices 106a, 106b in accordance with existing and conventional designs, and (ii) new chip testing devices 108a-108d in accordance with teachings provided herein. With reference to the remaining figures, the chip testing devices 106, 108 are explained in greater detail herein.

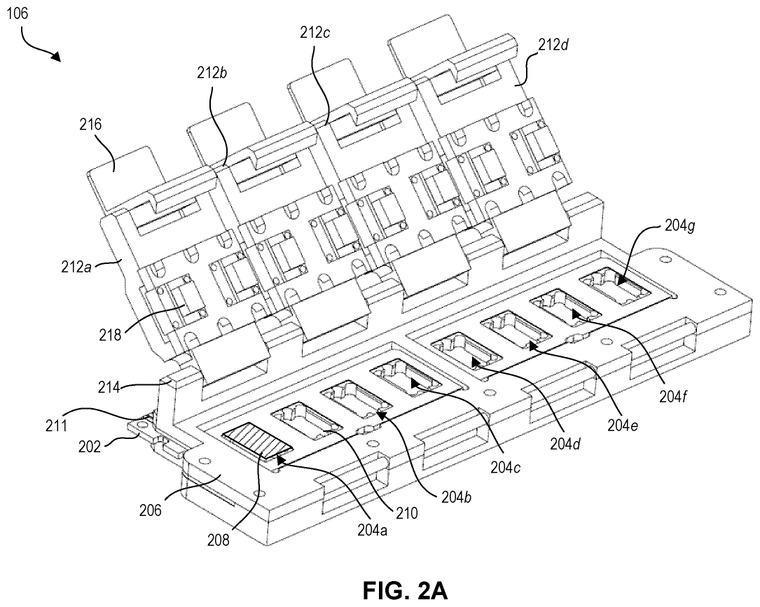

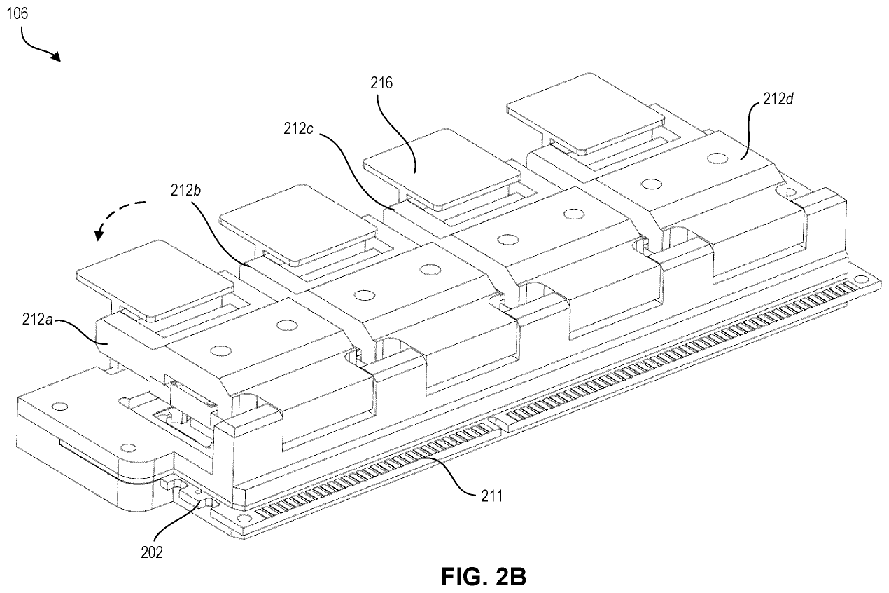

Reference is now made concurrently to FIGS. 2A and 2B, which show perspective views of an example chip testing device 106. Chip testing device 106 may be considered as an example of a conventional chip testing device design and may be referred to herein as a clamshell socket design or a particle testing fixture (e.g., a synchronous dynamic RAM (SDRAM) particle testing fixture).

As shown in FIG. 2A, chip testing device 106 includes a test board 202 (i.e., a PCB board), and one or more serially arranged “particle sockets” 204a-204g. The particle sockets 204a-204g are formed within a frame structure 206 (i.e., a metal frame) affixed to the test board 202. Each particle socket 204a-204g is adapted to removably receive an integrated circuit (IC) chip 208 (i.e., a RAM memory chip), with the frame 206 physically and electrically isolating consecutively arranged sockets 204a-204g.

Located within each socket 204a-204g is an electrical pad 210 (only one of which is numbered for ease of illustration). Each electrical pad 210 interfaces with electrical pins in an installed test chip 208 (i.e., electrical pins provided on an underside of the test chip). The electrical pads 210 may be formed on the test board 110 and may electrically couple the mounted chip 208 to an electrical plug-in portion 211 of the test board 202 (FIG. 2B). The plug-in portion 211 is, in turn, insertable into the electrical interface 104 of the motherboard 102 (FIG. 1) such as to interface each memory chip 208, in each socket 204a-204g, to the motherboard 102.

As shown in FIG. 2A, the chip testing device 106 can also include one or more lever members 212a-212d. Each lever member 212a-212d is rotatably attached to the frame 206 via a pivoting mechanism 214 (i.e., a rotating hinge), and rotates between an open position (FIG. 2A) and a closed position (FIG. 2B). In the open position (FIG. 2A), the lever members 212 rotate away from the frame 206 to expose the particle sockets 204a-212d. In the closed position (FIG. 2B), the lever members 212 rotate to overlap the frame 206 and to otherwise secure the test chips 208 inside the sockets 204a-212d. In some cases, a handle 216 is provided to facilitate rotation of the levers 212 between the open and closed positions. Each lever member 212 may also include a protruding press block 218 which, in the closed position, urges the mounted chips 208 into further electrical engagement with the socket's electrical pad 210.

The inventors have appreciated a number of significant disadvantages with the conventional chip testing device illustrated in FIGS. 2A and 2B.

First, the conventional chip testing device 106 is mechanically complex, and requires fabricating and combining a number of large movable mechanical components (i.e., the large frame, lever members and press blocks). This can result in high production costs, especially for volume manufacturing of chip testing devices. Second, owing to the large and “thick” structure of each particle socket 204a-212d, the chip testing device 106 occupies a large footprint on the motherboard 102 (FIG. 1). This can be problematic for small motherboards 102 having a dense layout configuration and an economy of space. Additionally, as only a few chip testing devices 106 can be mounted concurrently to the motherboard 102 in close proximity (i.e., owing to their thick structure), the chip testing devices 106 can be said to have a low slot utilization rate and resulting in low testing efficiency. Third, because the size of the chip testing devices 106 is larger than that of an ordinary memory bar, the circuit on the test board 202 is also large, which results in an increased wiring length and reduced signal integrity for signals flowing between the mounted chips 208 and the motherboard 102.

In view of the foregoing, there is a desire for a chip testing device which can address at least some of the aforementioned challenges inherent in conventional chip testing device designs.

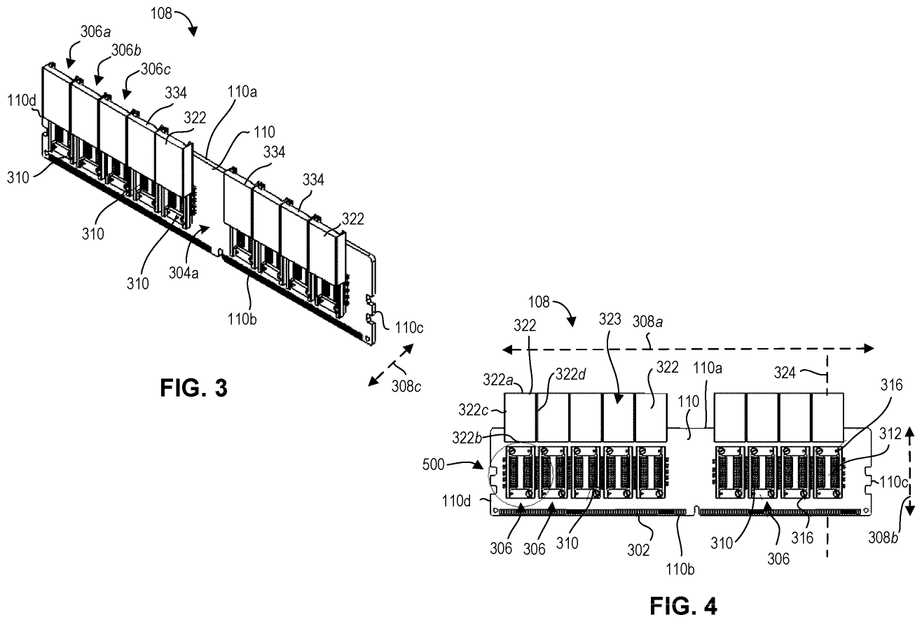

Reference is now made to FIGS. 3 to 8D, which illustrate various views of an example embodiment of a chip testing device 108 in accordance with the teachings herein. The chip testing device 108 illustrated in these figures may be referred to herein as a “slide-type” chip testing device.

As provided in greater detail, the provided slide-type chip testing device 108 provided can include a plurality of chip sockets that each comprise a positioning fixture (i.e., a positioning frame) for retaining a test chip. Each chip testing device 108 can also include one or more integrated slide covers that slide over the positioning frame to retain test chips mounted inside the chip sockets.

In contrast to existing chip testing devices (e.g., chip testing device 106 in FIGS. 2A and 2B), the provided slide-type device 108 has a simpler structure and an overall reduced size. In at least one example embodiment, the existing chip testing device may have dimension parameters of 45 millimeters (mm) (height)×40 mm (width)×15 mm (depth), with a weight of 200 g, while the slide-type device 108 may have dimension parameters of 35 mm (height)×18 mm (width)×7 mm (depth), with a weight of approximately 50 g. It will be understood that the reduction in size and weight is owing to the use of different structural elements (i.e., using sliding covers rather than large lever-type press blocks), which can be fashioned with smaller/leaner dimensions, and are generally more light weight in nature.

To this end, the simpler structure can allow for reduced production time and cost, while the overall reduced size can allow the device 108 to occupy a smaller footprint on the motherboard 102. In particular, by occupying a smaller footprint on a motherboard 102, the slot utilization rate is increased and a larger number of chip testing devices 108 may be concurrently accommodated in close proximity on the motherboard 102 such as to increase the overall testing efficiency. For example, in FIG. 1, the same area accommodating only two conventional chip testing devices 106 can accommodate up to four chip testing devices 108 in accordance with the teachings herein. Additionally, as the chip sockets are made smaller and thinner, they can be sized to fit on only a single dual in-line memory module (DIMM), which may be important for testing worst case conditions, such as fully-loaded conditions.

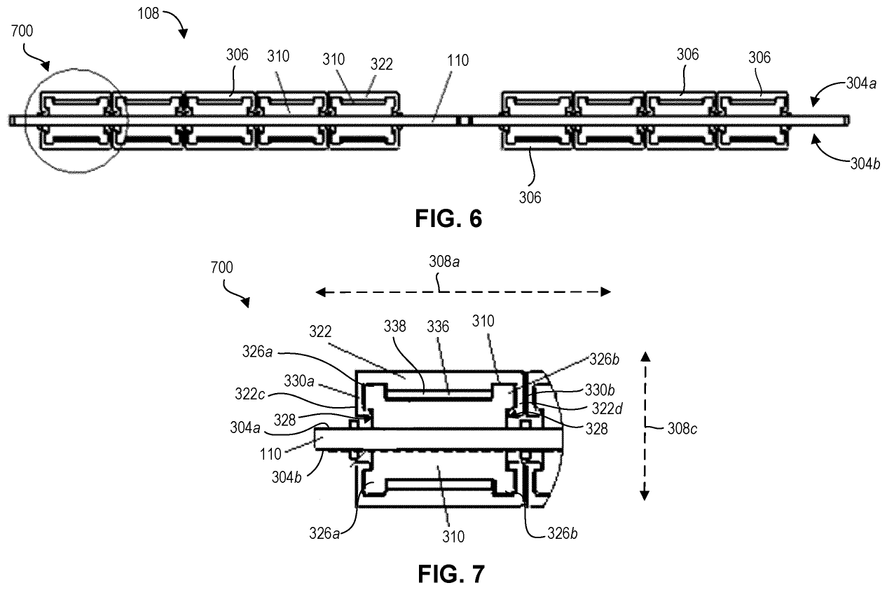

The slide-type device 108 is explained herein in greater detail. As shown in FIGS. 3 to 8D, each chip testing device 108 includes a test board 110. Test board 110 may be a printed circuit board (PCB) having one or more electrical connections. In the illustrated example, the test board 110 has a generally planar design comprising two opposing lateral surfaces (also referred to herein as mounting surfaces)—a first lateral surface 304a and an opposed second lateral surface 304b (FIG. 6).

As best shown in FIGS. 3 and 4, the test board 110 can have a length defined along a longitudinal horizontal axis 308a, a height defined along a vertical axis 308b and a width or thickness defined along a transverse axis 308c. In the upright position—i.e., when the top of the test board 110 is positioned over the bottom of the test board 110—the test board 110 may include a top longitudinal edge 110a and an opposed bottom longitudinal edge 110b, each extending along the longitudinal axis 308a (FIG. 4). Test board 110 can also include a first side edge 110c and an opposed second side edge 110d, each extending along the vertical axis 308b, i.e., as between the top and bottom edges 110a, 110b. It will be generally understood that reference herein to “top”, “bottom” and “side” are intended to be relative positional terms that are used for ease of description and that any other suitable orientational terms can be used having regard to the orientation and placement of the test board. In other embodiments, the test board 110 may also have any other suitable shape, design or configuration comprising any desired number of surfaces.

As further shown, a portion of the test board 110 may comprise an insertion portion 302, or an electrical plug-in portion (FIG. 4). The insertion portion 302 can be used, for example, to electrically interface the test board 110 with the motherboard 102. For example, the test board 110 may be placed in a mounted (or inserted) position relative to the motherboard 102 via the electrical interface 104. In at least one embodiment, the insertion portion 302 may extend along at least a portion of the bottom longitudinal edge 110b of the test board 110. In other embodiments, the insertion portion 302 may be extend along any other suitable portion of the board 110 (i.e., along one or more of the edges 110a, 110b and/or 110c).

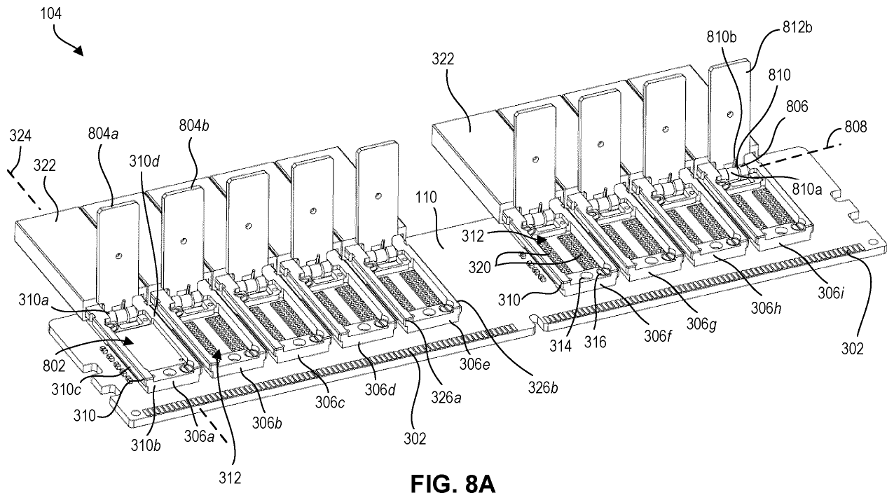

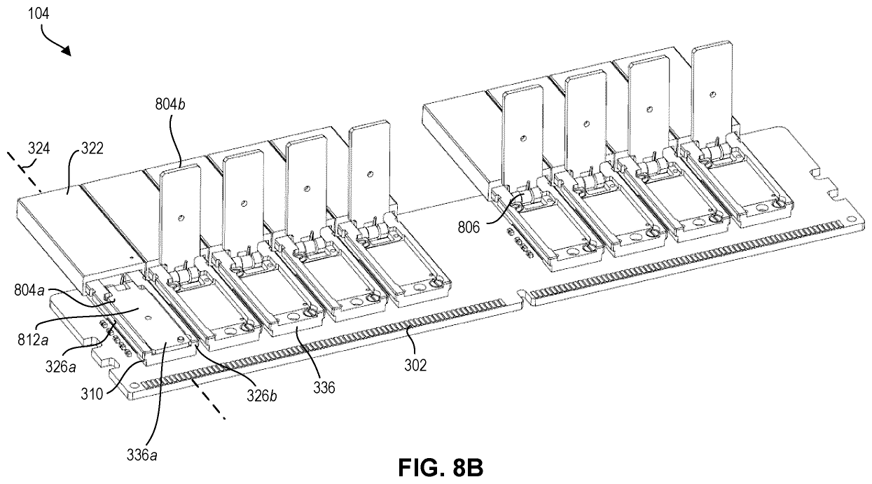

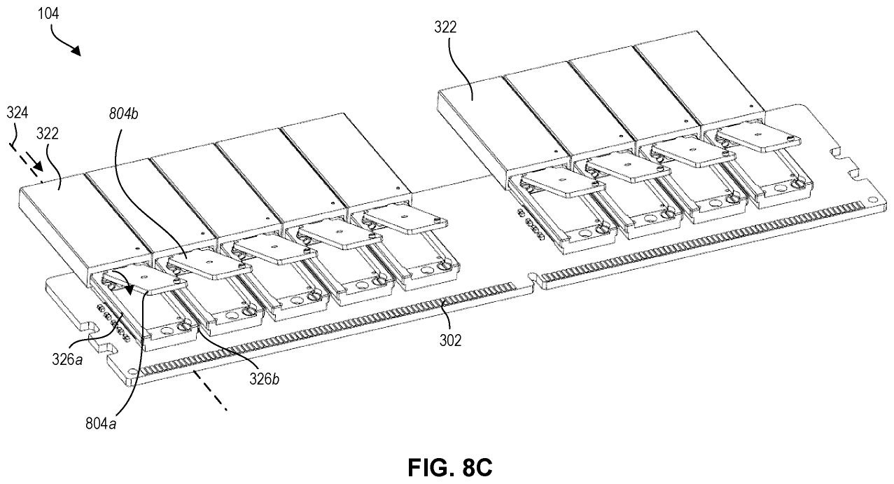

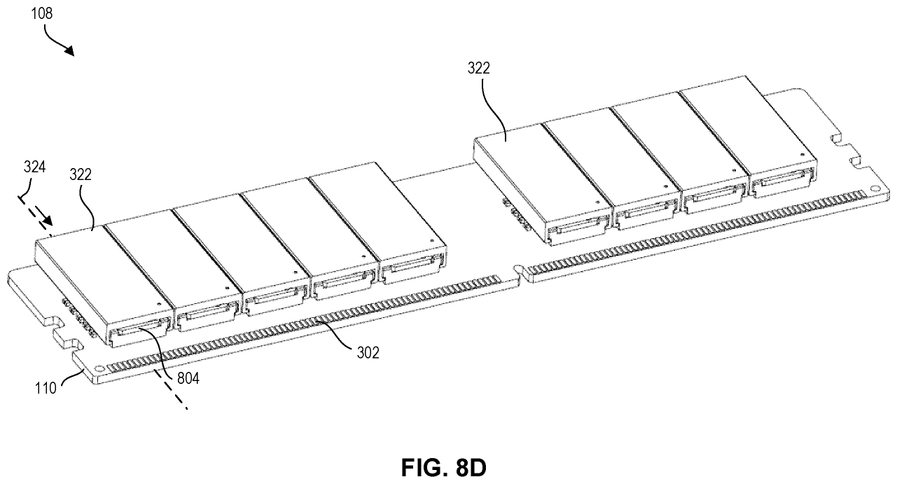

As shown in FIG. 3, one or more chip sockets 306 (i.e., 306a-306c) may be located on the board 110. Each socket 306 may be adapted, or structured, to receive a single test chip (i.e., an IC memory chip 802 in FIG. 8A). The chip sockets 306 may be disposed on either one or both surfaces 304a, 304b of the test board 110. FIG. 6 illustrates an example embodiment where chip sockets 306 are disposed on both lateral surfaces 304a, 304b of the board 110. By accommodating chips sockets 306 on both lateral surfaces 304, the provided design may allow for a greater number of chips to be concurrently tested using a single board. This can be contrasted to the chip testing device 106 of FIGS. 2A and 2B, whereby sockets are only provided on a single lateral surface of the test board owing to the large structure of each socket.

In the illustrated embodiments, the chip sockets 306, on each lateral surface 304a, 304b, are serially arranged side-by-side, along the longitudinal axis 308a. This configuration may maximize the number of sockets located on a given surface. Each socket 306 may further extend vertically, at least part way, along the vertical axis 308b, as between the top edge 110a and bottom edges 110b of the test board 110. In other embodiments, the sockets 306 may have any other suitable positional arrangement on any surface of the test board 110.

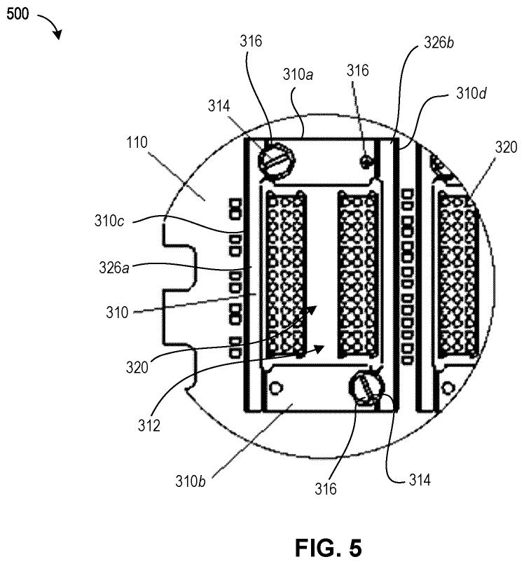

In at least one embodiment, each socket 306 is formed of a chip positioning fixture 310 (see e.g., FIGS. 3, 4 and 8A) which forms a frame structure. The positioning fixture 310 may define an at least partially enclosed area 312 where a test chip 802 can be inserted or mounted (also referred to herein as a chip mounting area 312). For example, as best shown in FIGS. 5 and 8A, in the upright position, the positioning fixture 310 may define an exposed mounting area 312 located between a top edge 310a, an opposed bottom edge 310b, and two laterally opposed side edges 310c, 310d that extend between the top and bottom edges 310a, 310b. In other embodiments, the positioning fixture 310 may not require all four edges in order to define the mounting area 312. For example, in some cases, the positioning fixture 310 may only include one or more edges (i.e., only the top and bottom edge 310a, 310b or only the two lateral edges 310c, 310d) to define a mounting area 312).

While the illustrated embodiment shows the edges of the positioning fixture 310 as being generally parallel to the edges of the test board 110, in other cases, the edges may be disposed at any other relative angle with respect to the test board edges. Further, while the positioning fixture 310 is illustrated as being formed from a single integral piece, in other cases, the positioning fixture 310 may be formed from any number of connected, partially connected or disconnected pieces. For example, each edge of the positioning fixture 310 may be a separate and disconnected component fixed to the test board 110.

In the illustrated example, the edges of the positioning fixture 310 define a generally rectangular mounting area 312, which can complement the generally rectangular shape of a mounted test chip (e.g., chip 802 in FIG. 8A). The positioning fixture 310 may also define a mounting area 312 having an area size that is proximal in size to the area size of the received test chip 802. This configuration of shape and size for the mounting area 312 may provide a closer tight fit engagement between a mounted test chip and the positioning fixture, i.e., so as to secure or retain the test chip 802 inside the positioning fixture 310. In other embodiments, the positioning fixture 310 may have any other suitable shape or design.

The positioning fixture 310 may be secured (or attached) to the test board 110 in any manner known in the art. In at least one embodiment, each positioning fixture 310 may include one or more mounting holes 314 (see enlarged view 500 of FIG. 5). For example, in the illustrated embodiment, four mounting holes 314 are provided at each corner of the positioning fixture 310. The mounting holes 314 may receive fasteners 316 (i.e., screws, bolts, etc.), which pass through the holes 314 and into corresponding installation holes located on the test board 110, i.e., installation holes (not shown) aligned on the test board 110 and located beneath the positioning fixture 310. In this configuration, the positioning fixture 310 may be removably secured to the test board 110 via the fasteners 316. In other embodiments, the positioning fixture 310 may be secured, for example, via adhesive paste, etc.

As best shown in FIGS. 5 and 8A, the mounting area 312, defined by the positioning fixture 310, can include one or more electrical contact pads 320. Electrical contact pads 320 can include electrical pins for electrically interfacing with corresponding pins on a mounted test chip 802. The electrical contact pads 320 may be formed (i.e., printed) directly on the test board 110, and may be electrically coupled to the test board insertion portion 302. Accordingly, once the test chip 802 is mounted inside the mounting area 312, the test chip 802 electrically couples to the insertion portion 302, via the electrical contact pad 320. This can allow interfacing the test chip 802 with the motherboard 102 when the insertion portion 302 is received inside the motherboard's electrical interface 104.

With reference to FIGS. 3-4 and 8A-8D, in at least one embodiment, each chip socket 306 may also include a corresponding sliding cover 322. Each sliding cover 322 may be movable between an open position (FIGS. 8A-8C) and a closed position (FIG. 8D). In the open position, the mounting area 312, of a respective socket 306, is exposed to allow insertion of a test chip 802 in the socket 306. In the closed position, the sliding cover 322 moves and covers over the mounting area 312 so as to releasably secure the mounted test chip 802 inside the area 312. The sliding cover 322 may also apply some pressure to urge the test chip 802 into closer (e.g., firmer) electrical engagement with the electrical pad 320 when moved into the closed position.

Each sliding cover 322 can translate along a longitudinal translation axis 324 between the open position and the closed position (FIGS. 4 and 8A). In at least one embodiment, the translation axis 324 may be disposed generally parallel to the vertical axis 308b, and orthogonal to the longitudinal axis 308a (FIG. 4). In other embodiments, the translation axis 324 may be oriented in any desired angle or orientation relative to the axes 308a, 308b and/or 308c when the socket is oriented in a like manner.

In some embodiments, in the open position, at least a portion of the sliding cover 322 may be initially disposed above the mounting area 312 (FIG. 3). To move the sliding cover 322 into the closed position, a downward force may be applied to push the sliding cover 322, along translation axis 324, such that the sliding cover 322 moves toward the bottom longitudinal edge 110b of the test board 110. A reverse upward force may also be applied to push the sliding cover 322 back into the open position. In other embodiments (not shown), a reverse configuration may be possible whereby at least a portion of the sliding cover 322 may be disposed below the mounting area 312 in the open position. In this configuration, an upward force may be applied to push the sliding cover 322, along translation axis 324, toward the board's top longitudinal edge 110a into the closed position, and a downward force can be applied to push the cover 322 back into the open position. It will be understood here again that reference to “downward” and “upward” are relative terms that depend only on the orientation of the test device 108. For example, in FIG. 8D, the test device 108 may be oriented on its lateral surface, in which case lateral force motions can be used to push the sliding cover 322 along translation axis 324 into the closed or open positions.

The sliding covers 322 are used to secure test chips inside the chip sockets 306 and press the chips into engagement with each socket's electrical pad 320. However, in contrast to the lever members 212 in device 106, the use of a sliding door mechanism offers a lighter, smaller and simpler moving mechanical structure. The sliding doors can be simply moved between the open and closed positions with a single hand motion, and with minimal user effort. Further, while the lever members 212 in FIGS. 2A and 2B must be rotated in a direction pointing away from the test board, the sliding covers 322 can move along a translation axis 324 located substantially in the same plane as the test board 110. Accordingly, the space required to move the sliding covers 322 between the open and closed positions is greatly minimized.

Referring now to FIGS. 5-7 and 8A-8D, any suitable translative sliding mechanism known in the art can be used to translate the sliding cover 322 between the open and closed positions. In the illustrated example embodiments, the sliding cover 322 is removably secured to, and slides over, the positioning fixture 310.

In at least one embodiment, each positioning fixture frame 310 may include two convex strips 326a, 326b which secure and guide the motion of the sliding cover 322. The convex strips 326 can extend, at least partially, along the length of the positioning fixture's side edges 310c, 310d (FIG. 5) and may extend radially outwardly from the fixture's edges 310c, 310d (FIGS. 6 and 7).

As shown in FIG. 7 (showing an enlarged view 700), each of the convex strips 326 may be formed by a protruding member. The protruding member can extend outwardly (i.e., along the longitudinal axis 308a), and can include a hanging portion that is spaced apart and away from the test board surface 304, i.e., along transverse axis 308c. An inset groove 328 can define the traverse space between each protruding strip 326 and the respective board surface 304.

In the illustrated embodiments, the convex strips 326 are integrally formed with the positioning fixture 310. In other cases, however, the convex strips 310 may be separate components that are adjoined (or affixed) to the positioning fixture 310. In still other embodiments, the convex strips 310 may be separate from the positioning fixture 310. For example, the positioning fixture 310 may simply comprise a top edge 310a and a bottom edge 310b, and accordingly, the convex strips 326 may form separate components that are affixed to the test board 110 and extend between the top and bottom edges 310a, 310b.

As shown by way of example in FIG. 4, each sliding cover 322 may have a surface plate 323 (i.e., which overlies the mounting area 312 in the closed position), which includes a top edge 322a, an opposing bottom edge 322b, and side edges 322c, 322d extending between the top and bottom edges 322a, 322b. In the illustrated example, the sliding cover 322 may have a generally rectangular shape that complements the rectangular shape of the positioning fixture 310 (and test chip 802). In other embodiments, the sliding cover 322 may have any other suitable shape, design or configuration. The sliding cover 322 may also be sized to fully (or partially) cover over the mounting area 312 in the closed position.

Referring to FIG. 7, each of the side edges 322c, 322d, of the surface plate 323, may include a respective flanged member 330a, 330b. The flanged members 330 may extend away from the surface plate 323, and may also extend partially along the length of each side edge 322c, 322d. When the sliding cover 322 is in an engaged position with the positioning fixture 310, the flanged members 330 are structured to at least partially wrap around the outer sides of the positioning fixture's convex strips 326a, 326b. In some embodiments, a portion of each flanged member 330 may be inserted into the inset groove 328 to further engage the sliding cover 322 to the convex strips 326. In this configuration, the flanged members 330 mate with the convex strips 326 such that the engagement of the flanged members 330 and convex strips 326 guide the sliding motion of the cover 322 between the open and closed positions (FIGS. 8A-8D). The convex strips 326 may accordingly prevent dislocation of the sliding cover 322 during the translation motion, and provide a stable sliding structure.

A motion limiting mechanism may also be provided to prevent the sliding cover 322 from “over sliding” beyond the closed position. In the illustrated embodiments, the limiting mechanism may be provided on the sliding cover 322. For example, as shown in FIG. 3, a limiting plate 334 may extend along at least a portion of the top edge 322a of the sliding cover 322, and can extend rearwardly and away from the cover's front plate 323 (i.e., extending rearwardly in the same direction as the flanged members 330). In the closed position, the limiting plate 334 may abut and engage the top edge 310a of the positioning fixture 310, thereby delimiting further downward movement of the sliding cover 322 beyond the closed position (i.e., assuming the chip testing device 108 is in the upright position). In other embodiments, where the sliding cover 322 is configured in a reverse manner to slide upwardly into the closed position (rather than downwardly), the limiting plate 344 may be located along the bottom edge 322b of the cover 322, and can abut against the bottom edge 310b of the positioning fixture 310. In still other embodiments, rather than the limiting plate 334 abutting against the bottom or top edges of the positioning fixture, the plate 334 can abut against any other structure directly or indirectly fixed or integrated onto the test board 110. As well, any other suitable motion limiting mechanism can be provided to prevent or restrict over-extension of the sliding cover 322 beyond the closed position.

In some embodiments, each chip socket 306 can further include a locking mechanism to secure the sliding cover 322 in the closed position. For example, as shown in FIG. 7, another end of the sliding cover 322—i.e., opposite the end having the limiting plate 334 (i.e., a bottom edge 322b of the sliding cover)—may include a clamping member 336. When the sliding cover 322 is in the closed position, the clamping member 336 may be configured to engage a corresponding clamping slot 338 on the positioning fixture 310 (i.e., on the lower edge 310b of the positioning fixture 310) (FIG. 8B). Alternatively, when the slide cover 322 is moved in the open position, the clamping member 336 may disengage the clamping slot 328,

[symbol]

One or more sockets 306 may also include a rotatable flipping member (also referred to herein as a rotating member). For example, as shown in FIGS. 8A-8D, each socket 306 may include a flipping member 804 that translates between an un-rotated position (e.g., flipping members 804a, 804b in FIG. 8A) and a fully rotated position (e.g., flipping member 804a in FIG. 8B).

In the unrotated position, the flipping member 804 is rotated away from the mounting area 312 so as to at least partially expose the area 312. In other words, the flipping member 804 may extend away from the test board 110 in the unrotated position to allow inserting and mounting a testing chip 802 in the area 312. In the fully rotated position, the flipping member 804 may cover at least part of the mounting area 312, and may overlap at least part of an inserted test chip 802.

The addition of the flipping member 804 to the chip testing device 804 may provide a number of appreciated advantages. For example, the flipping member 804 in the rotated position may prevent scratches to a mounted test chip 802. For instance, as the sliding cover 322 is moved into the closed position, the flipping member 804 may be interposed between the sliding cover 322 and the mounted chip 802 such as to protect the mounted chip 802 from being scratched. This flipping member 804 may also facilitate smoother sliding of the sliding cover 322 between the open and closed positions since, in some embodiments, the flipping member 804 can also assist in pressing down the test chip 802 into closer electrical engagement with the electrical contact pad 320 inside each socket 306 when the sliding cover is in the closed position. In particular, upon mounting the test chip 802 in the mounting area 312—the test chip 802 may initially protrude slightly higher than the top of the sliding cover 322. Accordingly, the flipping member 804 can be used to depress the test chip 802 downwardly prior to the sliding cover 322 being translated over the test chip 802 when being moved into the closed position. In some cases, the flipping member 804 can also act as a heat sink, since during testing, the test chip 802 may generate heat which can then dissipate more easily into the flipping member 804 located on top of the test chip 802.

In at least one embodiment, the flipping member 804 may be rotatably connected to the positioning fixture 310. For instance, one end of the flipping member 804 may be rotatably connected to the top edge 310a of the positioning fixture via a rotatable hinge mechanism 806 (FIG. 8A). The flipping member 804 can rotate about a rotational axis that is parallel to the translation axis 808 and the longitudinal axis 308a. Other rotation mechanisms known in the art may also be used to rotate the flipping member 804. In some cases, rather than rotating, the flipping member may translate between an unfolded position and a folded position in any manner known in the art.

In this illustrated example arrangement, the sliding cover 322 can be used to rotate the flipping member 804 from the unrotated position to the rotated position. For example, as best shown in FIG. 8C, as the sliding cover 322 is translated from the open position to the closed position, the cover 322 will abut or engage an outer surface 812a of the flipping member 804 (i.e., an outer surface that faces the cover 322 when the cover is in the closed position), and cause the flipping member 804 to rotate down into the fully rotated position (FIG. 8D). In this manner, the flipping member 804 may be rotated in a single motion when the sliding cover 322 is at least partially translated into the closed position.

In some cases, a biasing structure may be provided to bias the flipping member 804 in the unrotated position. For example, a biasing spring 810 (FIG. 8A) may be provided around the hinge mechanism 806, and may bias the flipping member 804 in the unrotated position. For example, the biasing spring 810 may include a first portion 810a that wraps around the hinge mechanism 806, and a second portion 810b which abuts against a surface 812b of the flipping member 804 that rotates into the socket 306 in the closed position. This configuration can ensure that when the sliding cover 322 is retracted back to the open position, the biasing spring 810 may automatically push the flipping member 804 back into the unrotated position without user intervention.

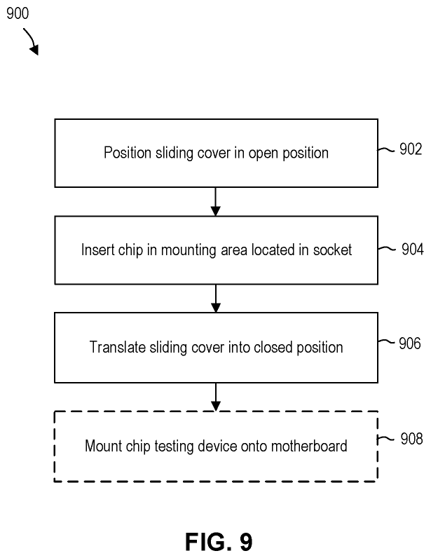

Reference is now made to FIG. 9, which illustrates an example embodiment of a method 900 for operating various embodiments of the chip testing device 108 that have been described in accordance with the teachings herein.

At act 902, the sliding cover 322 of a chip socket 306 may be initially positioned in an at least partially open position, thereby exposing the mounting area 312. In embodiments where the socket 306 also include a flipping member 804, at act 902, the flipping member 804 may also be positioned in an at least a partially unrotated (or un-flipped) position.

At act 904, a test chip 802 can be inserted into the mounting area 312 defined by the positioning fixture 310 of the chip socket 306.

At act 906, the sliding cover 322 may be translated into the closed position. In cases where the socket 306 includes a flipping member 804, the translation of the sliding cover 322 into the closed position also concurrently rotates (or flips) the flipping member 804 into the rotated position.

At act 908, in some cases, once the sliding cover 322 is in the closed position—the chip testing device 108 is electrically coupled to a motherboard 102, i.e., by inserting the insertion portion 302 into the motherboard's electrical interface 104 in FIG. 1. In other cases, more than one chip socket 306 may be filled with test chips prior to inserting the testing devices 108 onto a motherboard 102.

In view of the above, the various disclosed embodiments for a slide-type chip testing device 108 may provide for an easy to use mechanism that facilitates quick and rapid mounting and dismounting of test chips inside chip sockets. Additionally, as compared to prior designs, the chip testing device 108 may allow more chips to be tested concurrently owing to the smaller size of each chip socket 306 as well as the number of chip sockets 306 that may be accommodated on either surface of the test board. The testing device 108 also has a simpler mechanical structure, that reduces production cost. Further, the thinner and lighter structure of the chip testing device 108 can allow a greater number of devices to be concurrently located on a motherboard 102.

Various embodiments have been disclosed herein for a slide-type chip testing device 108.

In a first embodiment, there is provided a slide-type chip testing device 108 that includes a test board 110, whereby a portion of the test board 110 may comprise an insertion portion 302, or an electrical plug-in portion. Further, the test board 110 can include one or more chip sockets 306 (i.e., 306a-306c). Each socket 306 may be adapted, or structured, to receive a single test chip (i.e., an IC memory chip 802 in FIG. 8A). The chip sockets 306 may be disposed on either one or both surfaces 304a, 304b of the test board 110. As provided herein as well, each socket 306 can be formed of a chip positioning fixture 310 (see e.g., FIGS. 3, 4 and 8A) which forms a frame structure. The positioning fixture 310 may define an at least partially enclosed chip mounting area 312 where a test chip 802. The frame shape can facilitate installation of the chip. The mounting area 312, defined by the positioning fixture 310, can include one or more electrical contact pads 320 to enable an installed chip to electrically connect to the test board 110. Each chip socket 306 may also include a corresponding sliding cover 322. Each sliding cover 322 may be movable between an open position (FIGS. 8A-8C) and a closed position (FIG. 8D). Accordingly, after the chip is installed, the sliding cover 322 may be moved into the closed position to press the chips into engagement with the contact pad 320.

In this embodiment, the positioning fixture 310 in combination with the sliding cover 322 secures the chip located in the mounting area 312 and in direct contact with the electrical contact pads 320, so that ordinary circuits can be used on the board. Further, the finished device 108 is lighter and thinner, and the structure is simple, which not only reduces the production cost, but also reduces the overall thickness of the device 108. As well, the overall structure of the fixture 210 is closer to the memory chip itself. The device 108 can be placed in a test environment such as a high-density layout of the motherboard. Multiple devices 108 can be inserted into the slots arranged with small gaps on the general motherboard at the same time, which increases the slot utilization and improves the test efficiency.

In a second embodiment, there is provided a slide-type chip testing device 108 which includes all or some of the features of the first embodiment, and additionally includes the convex strips 326a, 326b as explained herein. As provided, the convex strips 326 are included on the positioning fixture frame 310 and can secure and guide the motion of the sliding cover 322. The convex strips 326 can extend, at least partially, along the length of the positioning fixture's side edges 310c, 310d (FIG. 5) and may extend radially outwardly from the fixture's edges 310c, 310d (FIGS. 6 and 7). Further, in this embodiment, the sliding cover 322 may include a surface plate 323 as well as flanged members 330a, 330b that are structured to at least partially wrap around the outer sides of the positioning fixture's convex strips 326a, 326b. A portion of each flanged member 330 may be inserted into the inset groove 328 of strips 326 to further engage the sliding cover 322 to the convex strips 326. In this embodiment, the flanged members 330 mate with the convex strips 326 such that the engagement of the flanged members 330 and convex strips 326 guide the sliding motion of the cover 322 between the open and closed positions (FIGS. 8A-8D). The convex strips 326 may accordingly prevent dislocation of the sliding cover 322 during the translation motion, and provide a stable sliding structure.

In a third embodiment, there is provided a slide-type chip testing device 108 which includes all or some of the features of the first embodiment, and may also include some or all of the features of the second embodiment. In this embodiment, the slide-type chip testing device 108 can further include a motion limiting mechanism to prevent the sliding cover 322 from “over sliding” beyond the closed position. For instance, as explained herein, the motion limiting mechanism may be provided on the sliding cover 322 and can comprise a limiting plate 334. Further each chip socket 306 can further include a locking mechanism to secure the sliding cover 322 in the closed position. For example, as provide herein, an end of the sliding cover 322—i.e., opposite the end having the limiting plate 334—may include a clamping member 336.

In a fourth embodiment, there is provided a slide-type chip testing device 108 which includes all or some of the features of the first embodiment, and may include some or all of the features of the second embodiment and/or third embodiment. In this embodiment, each positioning fixture 310 may additionally include one or more mounting holes 314 (see enlarged view 500 of FIG. 5). For example, four mounting holes 314 can be provided at each corner of the positioning fixture 310. The mounting holes 314 may receive fasteners 316 (i.e., screws, bolts, etc.), which pass through the holes 314 and into corresponding installation holes located on the test board 110, i.e., installation holes (not shown) aligned on the test board 110 and located beneath the positioning fixture 310. In this embodiment, the positioning fixture 310 may be removably secured to the test board 110 via the fasteners 316. In other cases, the positioning fixture 310 may be secured, for example, via adhesive paste, etc.

In a fifth embodiment, there is provided a slide-type chip testing device 108 which includes all or some of the features of the first embodiment, and may include some or all of the features of the second embodiment, third embodiment and/or fourth embodiment. In this embodiment, one or more sockets 306 may also include a rotatable flipping member as explained herein.

In a sixth embodiment, there is provided a slide-type chip testing device 108 that includes the features of the fifth embodiment, and also includes a biasing structure to bias the flipping member 804 in the unrotated position.

It will be understood that other embodiments of the device 108 are realizable having any combination of the above noted features, or any features previously described herein. While the applicant's teachings described herein are in conjunction with various embodiments for illustrative purposes, it is not intended that the applicant's teachings be limited to such embodiments as the embodiments described herein are intended to be examples. On the contrary, the applicant's teachings described and illustrated herein encompass various alternatives, modifications, and equivalents, without departing from the embodiments described herein, the general scope of which is defined in the appended claims.

1. A chip testing device comprising:
a test board having at least one mounting surface;
at least one chip socket located on one of the at least one mounting surface, wherein each of the at least one chip socket comprises:
a positioning fixture mounted to the at least one mounting surface, the positioning fixture defining a mounting area for mounting a chip;
a sliding cover that is slidably moveable between an open position and a closed position,
wherein,
in the open position, the mounting area is at least partially exposed to allow for mounting of the chip, and
in the closed position, the cover overlays at least a portion of the chip and the positioning fixture.

2. (canceled)

3. The device of claim 1, wherein the sliding cover is slidably engaged to the positioning fixture; and/or wherein one end the sliding cover includes a limiting plate that is adapted to delimit sliding of the sliding cover beyond the closed position.

4. (canceled)

5. The device of claim 43, wherein the sliding cover comprises a clamping member located at an opposite end relative to end of the sliding cover that includes the limiting plate, and
wherein the of the positioning fixture comprises a clamping slot that is compatible with the clamping member, and engagement of the clamping member and the clamping slot releasably secures the sliding cover in the closed position.

6. The device of claim 1, wherein the positioning fixture comprises a frame structure having a first edge, and a second edge opposite the first edge, wherein,
each of the first and second edges extend along a first axis of the test board between a respective first end and a respective opposed second end, and
each of the first and second edges define an area located therebetween that comprises the mounting area.

7. The device of claim 6, wherein the sliding cover is adapted to slide between the open position and the closed position along a translation axis that is parallel to the first axis; and/or wherein the sliding cover is adapted to slide from the open position to the closed position by sliding from the respective first end, of each of the first and second edges, towards the respective second end.

8. (canceled)

9. The device of claim 6, wherein at least a portion of at least one of the first and second edges comprises a protruding convex strip, and the sliding cover comprises at least one flanged member that is adapted to mate in a sliding engagement with the protruding convex strip.

10. The device of claim 6, wherein the positioning fixture further comprises a third edge and an opposed fourth edge, wherein each of the third and fourth edges extend between the first and second edges, and wherein each of the third and fourth edges extend along a second axis that is transverse to the first axis.

11. The device of claim 10, further comprising a rotatable flipping member that rotates between an unrotated position and a rotated position, wherein
in the unrotated position, the rotatable member extends away from the at least one mounting surface to at least partially expose the mounting area, and
in the rotated position, the rotatable member is rotated toward the at least one mounting surface to at least partially cover the mounting area.

12. The device of claim 11, wherein the rotatable member is rotatably mounted to the third edge of the positioning fixture; and/or the device further comprises a biasing member to bias the rotating member in the unrotated position.

13. (canceled)

14. (canceled)

15. (canceled)

16. The device of claim 11, wherein the sliding cover is adapted to move the rotatable member from the unrotated position to the rotated position when the sliding cover is translated from the open position to the closed position.

17. The device of claim 16, wherein when the sliding cover is in the closed position, the rotatable member is located between the sliding cover and the mounting area.

18. The device of claim 1, wherein one or more electrical contact pads are located in the mounting area, the one or more electrical contact pads being configured to electrical connect to electrical pins located on the chip mounted in the mounting area.

19. The device of claim 18, wherein the test board further comprises an insertion portion for electrically and mechanically coupling the device with a motherboard and the insertion portion comprises one or more electrical pins that are electrically connected to the one or more electrical contact pads.

20. The device of claim 19, wherein the insertion portion extends along an edge of the board.

21. The device of claim 1, wherein the at least one mounting surface comprises a plurality of chip sockets.

22. The device of claim 21, wherein the plurality of chip sockets are serially arranged along a longitudinal axis of the mounting surface; and/or wherein the at least one mounting surface comprises a first surface and an opposed second surface, and the plurality of chip sockets are located on each of the first and second surfaces.

23. (canceled)

24. The device of claim 1, wherein the positioning fixture includes one or more mounting holes, and the positioning fixture is mounted to the at least one surface of the test board using one or more fasteners that releasably engage the one or more mounting holes.

25. A chip testing device comprising:
a test board having at least one mounting surface;
at least one chip socket located on one of the at least one mounting surface, wherein each of the at least one chip socket comprises:
a positioning fixture mounted to the at least one mounting surface, the positioning fixture defining a mounting area for mounting a chip;
a sliding cover that is slidably moveable between an open position and a closed position, and
a rotatable flipping member that rotates between an unrotated position and a rotated position,
wherein,
in the open position of the sliding cover, the mounting area is at least partially exposed to allow for mounting of the chip, and
in the closed position of the sliding cover, the cover overlays at least a portion of the chip and the positioning fixture, and
in the unrotated position of the rotatable member, the rotatable member extends away from the at least one mounting surface to at least partially expose the mounting area, and
in the rotated position of the rotatable member, the rotatable member is rotated toward the at least one mounting surface to at least partially cover the mounting area.

26. The device of claim 25, wherein the rotatable member is rotatably mounted to an edge of the positioning fixture; and/or the device further comprises a biasing member to bias the rotating member in the unrotated position.

27. (canceled)

28. (canceled)

29. (canceled)

30. The device of claim 25, wherein the sliding cover is adapted to move the rotatable member from the unrotated position to the rotated position when the sliding cover is translated from the open position to the closed position.

31. The device of claim 30, wherein when the sliding cover is in the closed position, the rotatable member is located between the sliding cover and the mounting area.

32. A method of operating a chip testing device that is defined according to claim 1, the method comprising:
positioning a sliding cover in an open position;
inserting a chip in a mounting area, the mounting area being defined by a positioning fixture mounted to a surface of a test board of the chip testing device, the sliding cover being movably coupled to the positioning fixture; and
translating the sliding cover from the open position to the closed position.

33. (canceled)

34. (canceled)
